(19) United States
(12) Patent Application Publication
(10) Pub. No.: US 2025/0210502 A1
(43) Pub. Date: Jun. 26, 2025

(54) SEMICONDUCTOR PACKAGE

(71) Applicant: SAMSUNG ELECTRONICS CO., LTD., Suwon-si (KR)

(72) Inventor: Youngbae Kim, Suwon-si (KR)

(21) Appl. No.: 18/982,910

(22) Filed: Dec. 16, 2024

(30) Foreign Application Priority Data
Dec. 26, 2023 (KR) 10-2023-0191384

(51) Int. Cl. H01L 23/498; H01L 23/00; H01L 23/31; H01L 25/10; H01L 25/18; H10B 80/00

(52) U.S. Cl. CPC H01L 23/49838; H01L 23/49833; H01L 23/3128; H01L 24/16; H01L 24/32; H01L 24/73; H01L 25/105; H01L 25/18; H01L 2224/16225; H01L 2224/32225; H01L 2224/73204; H01L 2225/1023; H01L 2924/1815; H10B 80/00

(57) ABSTRACT

A semiconductor package includes a first RDL containing a first redistribution wiring structure, a first semiconductor chip on the first RDL, a first mold on the first RDL and covering the first semiconductor chip, a second RDL on the first mold and containing a second redistribution wiring structure, a first conductive post extending through the first mold and contacting the first and second redistribution wiring structures and being spaced apart from the first semiconductor chip in a horizontal direction by a first distance, and a second conductive post extending through the first mold, contacting the first and second redistribution wiring structures and being spaced apart from the first semiconductor chip in the horizontal direction by a second distance greater than the first distance. A volume of the first conductive post is smaller than a volume of the second conductive post.

### CROSS-REFERENCE TO RELATED APPLICATION

This application claims priority under 35 U.S.C. § 119 to Korean Patent Application No. 10-2023-0191384, filed on Dec. 26, 2023 in the Korean Intellectual Property Office (KIPO), the contents of which are herein incorporated by reference in their entirety.

### BACKGROUND

In fan-out wafer-level package (FOWLP) techniques, a conductive pad is interposed between a lower redistribution layer (RDL) and a lower semiconductor chip, and a conductive bump is interposed between an upper RDL and an upper semiconductor chip. The upper semiconductor chip and the lower RDL are electrically connected to each other through a copper post and the upper RDL.

Thus, the bonding state between the conductive pad and the conductive bump and the bonding state between the copper post and the upper RDL is important in the electrical connection in the FOWLP.

### SUMMARY

The present disclosure provides a semiconductor package having enhanced electrical characteristics.

In a general aspect, a semiconductor package includes: a first redistribution layer (RDL) containing a first redistribution wiring structure, a first semiconductor chip mounted on the first RDL, a first mold on the first RDL and covering the first semiconductor chip, a second RDL on the first mold and containing a second redistribution wiring structure, a first conductive post extending through the first mold between the first and second RDLs and contacting the first and second redistribution wiring structures and being spaced apart from the first semiconductor chip in a horizontal direction by a first distance, and a second conductive post extending through the first mold between the first and second RDLs and contacting the first and second redistribution wiring structures and being spaced apart from the first semiconductor chip in the horizontal direction by a second distance that is greater than the first distance. A volume of the first conductive post may be smaller than a volume of the second conductive post.

In another general aspect, a semiconductor package includes: a first redistribution layer (RDL) containing a first redistribution wiring structure, a first semiconductor chip mounted on the first RDL, a mold on the first RDL and covering the first semiconductor chip, a second RDL on the mold and containing a second redistribution wiring structure, a first conductive post extending through the mold between the first and second RDLs and contacting the first and second redistribution wiring structures, being spaced apart from the first semiconductor chip in a horizontal direction by a first distance, and including a first lower portion having a first width and a first upper portion on and contacting the first lower portion and having a second width smaller than the first width, a second conductive post extending through the mold between the first and second RDLs and contacting the first and second redistribution wiring structures, being spaced apart from the first semiconductor chip in the horizontal direction by a second distance that is greater than the first distance, and including a second lower portion having a third width and a second upper portion on and contacting the second lower portion and having a fourth width greater than the third width

In another general aspect, a semiconductor package includes: a first redistribution layer (RDL) containing a first redistribution wiring structure, a conductive connection member beneath a lower surface of the first RDL, a first semiconductor chip mounted on the first RDL, a first mold on the first RDL and covering the first semiconductor chip, a second RDL on the first mold and containing a second redistribution wiring structure, a second semiconductor chip mounted on the second RDL, a second mold on the second RDL and covering the second semiconductor chip, first conductive posts each extending through the first mold between the first and second RDLs and contacting the first and second redistribution wiring structures and being arranged in a rectangular ring shape at a first distance from the first semiconductor chip in a horizontal direction in a plan view, and second conductive posts each extending through the first mold between the first and second RDLs and contacting the first and second redistribution wiring structures and being arranged in a rectangular ring shape at a second distance greater than the first distance from the first semiconductor chip in the horizontal direction. A volume of each of the first conductive posts may be smaller than a volume of each of the second conductive posts.

In some implementations, the conductive posts electrically connecting the lower RDL and the upper RDL may have upper surfaces at substantially the same height regardless of the distance from the semiconductor chip surrounded by the conductive posts, so that the electrical connection between the lower and upper RDLs may be enhanced. In this specification, “substantially the same” indicates that two values agree to within, for example, 1%, 5%, or 10%.

### BRIEF DESCRIPTION OF THE DRAWINGS

FIGS. 1 and 2 are cross-sectional views illustrating an example of a semiconductor package, and FIG. 3 is a plan view illustrating an example of a layout of conductive posts in the semiconductor package.

FIGS. 4 to 9 are plan views and cross-sectional views illustrating an example of a method of manufacturing a semiconductor package.

FIGS. 10 and 11 are cross-sectional views illustrating examples of semiconductor packages.

FIG. 12 is a cross-sectional view illustrating examples of semiconductor packages.

FIGS. 13 and 14 are cross-sectional views illustrating an example of a method of manufacturing a semiconductor package.

FIG. 15 is a cross-sectional view illustrating an example of a semiconductor package.

FIGS. 16 and 17 are cross-sectional views illustrating an example of a method of manufacturing a semiconductor package.

FIG. 18 is a cross-sectional view illustrating an example of a semiconductor package.

FIG. 19 is a cross-sectional view illustrating an example of an electronic device.

Hereinafter, a direction substantially parallel to an upper surface of a wafer, a substrate or an interposer may be referred to as a horizontal direction, and a direction substantially perpendicular to the upper surface of the wafer, the substrate or the interposer may be referred to as a vertical direction.

### DETAILED DESCRIPTION

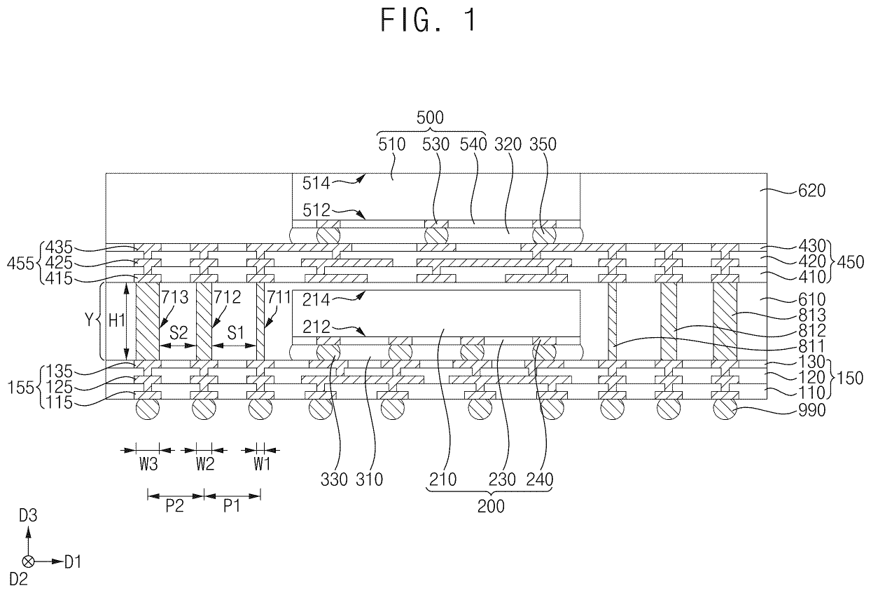

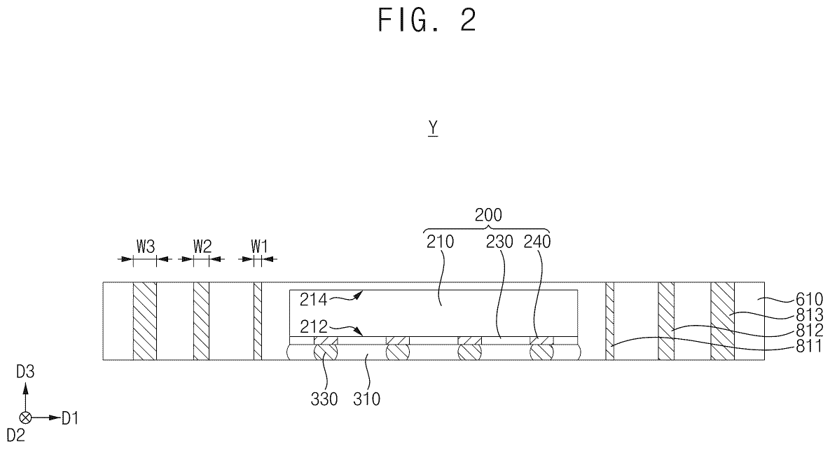

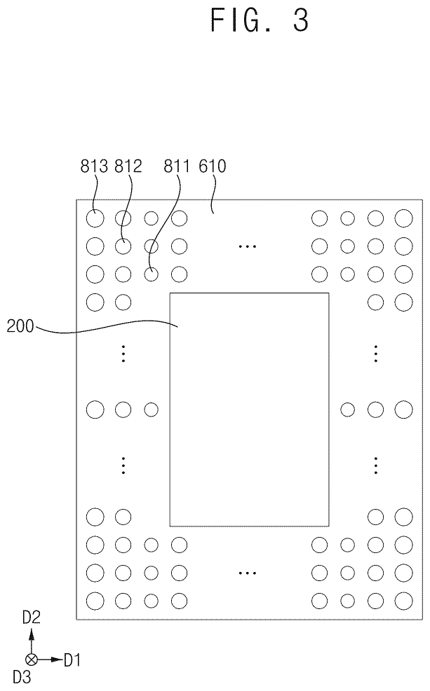

FIGS. 1 and 2 are cross-sectional views illustrating an example of a semiconductor package, and FIG. 3 is a plan view illustrating an example of a layout of conductive posts in the semiconductor package. FIG. 2 is an enlarged cross-sectional view of region Y of FIG. 1.

Referring to FIGS. 1 to 3, the semiconductor package includes a second conductive connection member 330, a first semiconductor chip 200, a second redistribution layer (RDL) 450, a third conductive connection member 350 and a second semiconductor chip 500 sequentially stacked on a first RDL 150.

The semiconductor package further includes first to third conductive posts 811, 812 and 813, first and second molds 610 and 620, first and second bonding layers 310 and 320 and a first conductive connection member 990.

In some implementations, the first RDL 150 may include insulation layers and a first redistribution wiring structure 155 in the insulation layers, and the first redistribution wiring structure 155 may include, for example, redistribution wirings, vias, contact plugs, conductive pads, etc.

FIG. 1 shows that the first RDL 150 includes first, second and third insulation layers 110, 120, and 130 sequentially stacked in the vertical direction, and the first redistribution wiring structure 155 includes a first conductive pad 115, a first redistribution wiring 125 and a second redistribution wiring 135 sequentially stacked. However, the present disclosure is not limited thereto. In some implementations, the first RDL 150 may include less than or more than three insulation layers, and the first redistribution wiring structure 155 may include redistribution wirings, vias, contact plugs, contact pads, etc., having various layouts.

The first and second redistribution wirings 125 and 135 may serve as second and third conductive pads, respectively, the first redistribution wiring 125 may contact an upper surface of the first conductive pad 115, and the second redistribution wiring 135 may contact an upper surface of the second conductive pad.

In some implementations, each of the first to third insulation layers 110, 120 and 130 may include an organic material. The organic material may include a polymer, for example, polyimide. Each of the first conductive pad 115 and the first and second redistribution wirings 125 and 135 may include, for example, aluminum, copper, tin, nickel, gold, platinum, or an alloy thereof.

The first conductive connection member 990 may be disposed beneath a lower surface of the first RDL 150, and may contact a lower surface of the first conductive pad 115. In some implementations, a plurality of first conductive connection members 990 may be spaced apart from each other in the horizontal direction according to the layout of the first conductive pads 115.

The first conductive connection member 990 may be mounted on and electrically connected to a package substrate, for example, a printed circuit board (PCB), a mother board, etc.

The first conductive connection member 990 may include, for example, a conductive bump, and the conductive bump may include a metal, for example, copper, aluminum, nickel, etc., or solder that is an alloy of tin, silver, copper, lead, etc.

The first semiconductor chip 200 may include a first substrate 210 having first and second surfaces 212 and 214 opposite to each other in the vertical direction, and a first insulating interlayer and a second insulating interlayer 230 sequentially stacked downwardly in the vertical direction beneath the first surface 212 of the first substrate 210.

FIGS. 1 to 3 show that a single first semiconductor chip 200 is disposed on the first RDL 150. However, the present disclosure is not limited thereto, and a plurality of first semiconductor chips 200 may be spaced apart from each other in the horizontal direction on the first RDL 150.

The first substrate 210 may include a semiconductor material, for example, silicon, germanium, silicon-germanium, or a III-V group compound semiconductor, for example, GaP, GaAs, GaSb, etc. In some implementations, the first substrate 210 may be a silicon-on-insulator (SOI) substrate or a germanium-on-insulator (GOI) substrate.

A circuit device, for example, a logic device or a memory device may be disposed beneath the first surface 212 of the first substrate 210, and may be covered by the first insulating interlayer. The logic device may include, for example, a controller, and the memory device may include a volatile memory device such as a DRAM device, an SRAM device, etc., or a non-volatile memory device such as a flash memory device, an EEPROM device, etc. The circuit device may include circuit patterns, for example, transistors, capacitors, resistors, inductors, etc.

The second insulating interlayer 230 may be disposed beneath the first insulating interlayer, and may contain a first wiring structure 240 therein. The first wiring structure 240 may include, for example, wirings, vias, contact plugs, conductive pads, etc. and the first wiring structure 240 is shown as a single structure in FIG. 1 in order to avoid the complexity of the drawing.

In some implementations, a first through electrode may extend through the first substrate 210 in the vertical direction and may contact a portion of the circuit device beneath the first surface 212 of the first substrate 210 to be electrically connected thereto. Alternatively, the first through electrode may extend through the first substrate 210 and the first insulating interlayer and may contact a portion of the first wiring structure 240 in the second insulating interlayer 230 to be electrically connected thereto.

Each of the first insulating interlayer and the second insulating interlayer 230 may include an oxide, for example, silicon oxide, and each of the first wiring structure 240 and the first through electrode may include a conductive material, for example, a metal, a metal nitride, a metal silicide, etc.

In some implementations, the first semiconductor chip 200 may be bonded with the first RDL 150 by a thermal compression bonding (TCB) process. Thus, the second conductive connection member 330 may be disposed between the first semiconductor chip 200 and the first RDL 150, and may contact a portion of the first wiring structure 240 in the second insulating interlayer 230 and a portion of the first redistribution wiring structure 155 in the first RDL 150, for example, the third conductive pad.

In some implementations, the second conductive connection member 330 may include first and second conductive patterns sequentially stacked downwardly in the vertical direction, the first conductive pattern may have a shape of a pad, and the second conductive pattern may have a shape of a bump. The first conductive pattern may include a metal, for example, nickel, copper, aluminum, gold, etc., and the second conductive pattern may include, for example, solder that is an alloy of tin, silver, copper, lead, etc.

The first bonding layer 310 may cover the second conductive connection member 330 and may fill a space between the first semiconductor chip 200 and the first RDL 150. The first bonding layer 310 may include a non-conductive film (NCF), for example, thermosetting resin.

In some implementations, the first semiconductor chip 200 may be bonded with the first RDL 150 by a hybrid copper bonding (HCB) process.

The first mold 610 may be disposed on the first RDL 150 and may cover a sidewall and an upper surface of the first semiconductor chip 200 and a sidewall of the first bonding layer 310. In some implementations, an upper surface of the first mold 610 may be higher than the upper surface of the first semiconductor chip 200. Alternatively, the first mold 610 may be substantially coplanar with the upper surface of the first semiconductor chip 200, and in this case, the first mold 610 may not cover the upper surface of the first semiconductor chip 200 but may cover the sidewall of the first semiconductor chip 200. The first mold 610 may have a first height H1 from an upper surface of the first RDL 150 in the vertical direction. The first mold 610 may include, for example, epoxy molding compound (EMC).

The first to third conductive posts 811, 812, and 813 may be disposed on the first RDL 150, and sidewalls of the first to third conductive posts 811, 812, and 813 may be covered by the first mold 610. Each of the first to third conductive posts 811, 812, and 813 may contact a portion of the first redistribution wiring structure 155, for example, an upper surface of the third conductive pad, and a portion of the second redistribution wiring structure 455, for example, a lower surface of the fourth conductive pad 415.

In some implementations, each of the first to third conductive posts 811, 812, and 813 may extend in the vertical direction, and an upper surface of each of the first to third conductive posts 811, 812, and 813 may have the first height H1 in the vertical direction from the upper surface of the first RDL 150. That is, the upper surfaces of the first to third conductive posts 811, 812 and 813 may be substantially coplanar with each other.

In some implementations, a width in the horizontal direction of each of the first to third conductive posts 811, 812, and 813 may be substantially constant in the vertical direction. The first to third conductive posts 811, 812, and 813 may have first to third widths W1, W2 and W3 in the horizontal direction. The third width W3 may be greater than the second width W2, and the second width W2 may be greater than the first width W1. Thus, a volume of the third conductive post 813 may be greater than a volume of the second conductive post 812, and the volume of the second conductive post 812 may be greater than a volume of the first conductive post 811.

In some implementations, a plurality of first conductive posts 811 may be arranged in a rectangular ring shape surrounding the first semiconductor chip 200 in a plan view, a plurality of second conductive posts 812 may be arranged in a rectangular ring shape surrounding the first conductive posts 811 in a plan view, and a plurality of third conductive posts 813 may be arranged in a rectangular ring shape surrounding the second conductive posts 812 in a plan view. Thus, the first conductive posts 811 may be closer to the first semiconductor chip 200 than the second conductive posts 812, and the second conductive posts 812 may be closer to the first semiconductor chip 200 than the third conductive posts 813.

In some implementations, a first pitch P1 in the horizontal direction between centers of the first and second conductive posts 811 and 812 may be substantially the same as a second pitch P2 in the horizontal direction between centers of the second and third conductive posts 812 and 813. In some implementations, a first distance S1 in the horizontal direction between the first and second conductive posts 811 and 812 may be greater than a second distance S2 in the horizontal direction between the second and third conductive posts 812 and 813.

The second RDL 450 may be disposed on the first mold 610 and the first to third conductive posts 811, 812 and 813. The second RDL 450 may include an insulation layers and a second redistribution wiring structure 455 in the insulation layers, and the second redistribution wiring structure 455 may include, for example, redistribution wirings, vias, contact plugs, conductive pads, etc.

FIG. 1 shows that the second RDL 450 includes fourth, fifth and sixth insulation layers 410, 420, and 430 sequentially stacked in the vertical direction, and the second redistribution wiring structure 455 includes a fourth conductive pad 415, a third redistribution wiring 425 and a fourth redistribution wiring 435 sequentially stacked. However, the present disclosure is not limited thereto. In some implementations, the second RDL 450 may include less than or more than three insulation layers, and the second redistribution wiring structure 455 may include redistribution wirings, vias, contact plugs, contact pads, etc., having various layouts.

Portions of the third and fourth redistribution wirings 425 and 435 may serve as fifth and sixth conductive pads, respectively, the second redistribution wiring 425 may contact an upper surface of the fourth conductive pad 415, and the fourth redistribution wiring 435 may contact an upper surface of the fifth conductive pad.

In some implementations, each of the fourth to sixth insulation layers 410, 420, and 430 may include an organic material. The organic material may include a polymer, for example, polyimide. Each of the fourth conductive pad 415 and the third and fourth redistribution wirings 425 and 435 may include, for example, aluminum, copper, tin, nickel, gold, platinum, or an alloy thereof.

The second semiconductor chip 500 may include a second substrate 510 having first and second surfaces 512 and 514 opposite to each other in the vertical direction, and a third insulating interlayer and a fourth insulating interlayer 530 sequentially stacked downwardly in the vertical direction beneath the first surface 512 of the second substrate 510.

FIGS. 1 to 3 show that a single second semiconductor chip 500 is disposed on the second RDL 450, however, the present disclosure is not limited thereto, and a plurality of second semiconductor chips 500 may be spaced apart from each other in the horizontal direction on the second RDL 450.

The second substrate 510 may include a semiconductor material, for example, silicon, germanium, silicon-germanium, or a III-V group compound semiconductor, for example, GaP, GaAs, GaSb, etc. In some implementations, the second substrate 510 may be a silicon-on-insulator (SOI) substrate or a germanium-on-insulator (GOI) substrate.

A circuit device, for example, a logic device or a memory device may be disposed beneath the first surface 212 of the second substrate 510, and may be covered by the third insulating interlayer. The logic device may include, for example, a controller, and the memory device may include a volatile memory device such as a DRAM device, an SRAM device, etc., or a non-volatile memory device such as a flash memory device, an EEPROM device, etc. The circuit device may include circuit patterns, for example, transistors, capacitors, resistors, inductors, etc.

The fourth insulating interlayer 530 may be disposed beneath the third insulating interlayer and may contain a second wiring structure 540 therein. The second wiring structure 540 may include, for example, wirings, vias, contact plugs, conductive pads, etc. However, the second wiring structure 540 is shown as a single structure in FIG. 1 in order to avoid the complexity of the drawing.

In some implementations, a second through electrode may extend through the second substrate 510 in the vertical direction and may contact a portion of the circuit device beneath the first surface 512 of the second substrate 510 to be electrically connected thereto. Alternatively, the second through electrode may extend through the second substrate 510 and the third insulating interlayer and may contact a portion of the second wiring structure 540 in the fourth insulating interlayer 530 to be electrically connected thereto.

Each of the third insulating interlayer and the fourth insulating interlayer 530 may include an oxide, for example, silicon oxide, and each of the second wiring structure 540 and the first second electrode may include a conductive material, for example, a metal, a metal nitride, a metal silicide, etc.

In some implementations, the second semiconductor chip 500 may be bonded with the second RDL 450 by a TCB process. Thus, the third conductive connection member 350 may be disposed between the second semiconductor chip 500 and the second RDL 450 and may contact a portion of the second wiring structure 540 in the third insulating interlayer 530 and a portion of the second redistribution wiring structure 455 in the second RDL 450, for example, the sixth conductive pad.

In some implementations, the third conductive connection member 350 may include third and fourth conductive patterns sequentially stacked downwardly in the vertical direction, the third conductive pattern may have a shape of a pad, and the fourth conductive pattern may have a shape of a bump. The third conductive pattern may include a metal, for example, nickel, copper, aluminum, gold, etc., and the fourth conductive pattern may include, for example, solder that is an alloy of tin, silver, copper, lead, etc.

The second bonding layer 320 may cover the third conductive connection member 350 and may fill a space between the second semiconductor chip 500 and the second RDL 450. The second bonding layer 320 may include a non-conductive film (NCF), for example, thermosetting resin.

In some implementations, the second semiconductor chip 500 may be bonded with the second RDL 450 by an HCB process.

The second mold 620 may be disposed on the second RDL 450, and may cover a sidewall of the second semiconductor chip 500 and a sidewall of the second bonding layer 320. In some implementations, an upper surface of the second mold 620 may be substantially coplanar with an upper surface of the second semiconductor chip 500. Alternatively, the upper surface of the second mold 620 may be higher than the upper surface of the second semiconductor chip 500 and, in this case, the second mold 620 may also cover the upper surface of the second semiconductor chip 500. The second mold 620 may include, for example, EMC.

In the semiconductor package, each of the first to third conductive posts 811, 812, and 813 may be disposed on the first RDL 150 and may contact the upper surfaces of the third conductive pads included in the first redistribution wiring structure 155 and the lower surfaces of the fourth conductive pads 415 included in the second redistribution wiring structure 455 in the second RDL 450, so as to electrically connect the second semiconductor chip 500 bonded with the second RDL 450 and the first RDL 150.

The upper surfaces of the first to third conductive posts 811, 812, and 813 may have substantially the same height. Particularly, the first height H1 is substantially the same as the height of the upper surface of the first mold 610 covering the sidewalls of the first to third conductive posts 811, 812, and 813, and thus the upper surfaces of all of the first to third conductive posts 811, 812, and 813 may be exposed. If upper surfaces of first ones of the first to third conductive posts 811, 812, and 813 are lower than upper surfaces of second ones of the first to third conductive posts 811, 812, and 813, the upper surfaces of the first ones of the first to third conductive posts 811, 812, and 813 may be covered by the first mold 610, and thus may not contact the lower surface of the fourth conductive pad 415 of the second redistribution wiring structure 455.

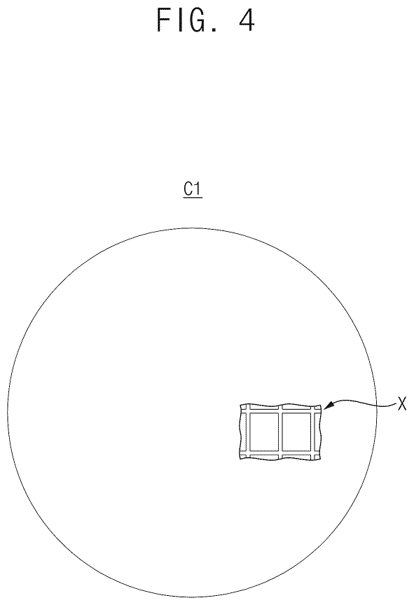

However, in some implementations, each of the upper surfaces of the first to third conductive posts 811, 812, and 813 may be substantially coplanar with the upper surface of the first mold 610, and thus may contact the lower surface of the fourth conductive pad 415 of the second redistribution wiring structure 455 so that the second semiconductor chip 500 may be electrically connected to the first RDL 150 through the first to third conductive posts 811, 812, and 813. As illustrated below with reference to FIGS. 4 to 9, the widths in the horizontal direction of the first to third conductive posts 811, 812, and 813 may have smaller values in this order, and thus each of the upper surfaces of the first to third conductive posts 811, 812, and 813 may be substantially coplanar with the upper surface of the first mold 610.

FIGS. 1 to 3 show that three conductive posts, that is, the first to third conductive posts 811, 812 and 813 surrounding the first semiconductor chip 200. However, the present disclosure is not limited thereto. In some implementations, the semiconductor package may include two or four conductive posts surrounding the first semiconductor chip 200 in a plan view. Widths in the horizontal direction of the conductive posts may have smaller values as the conductive posts are closer to the first semiconductor chip 200.

FIGS. 4 to 9 are plan views and cross-sectional views illustrating an example of a method of manufacturing a semiconductor package.

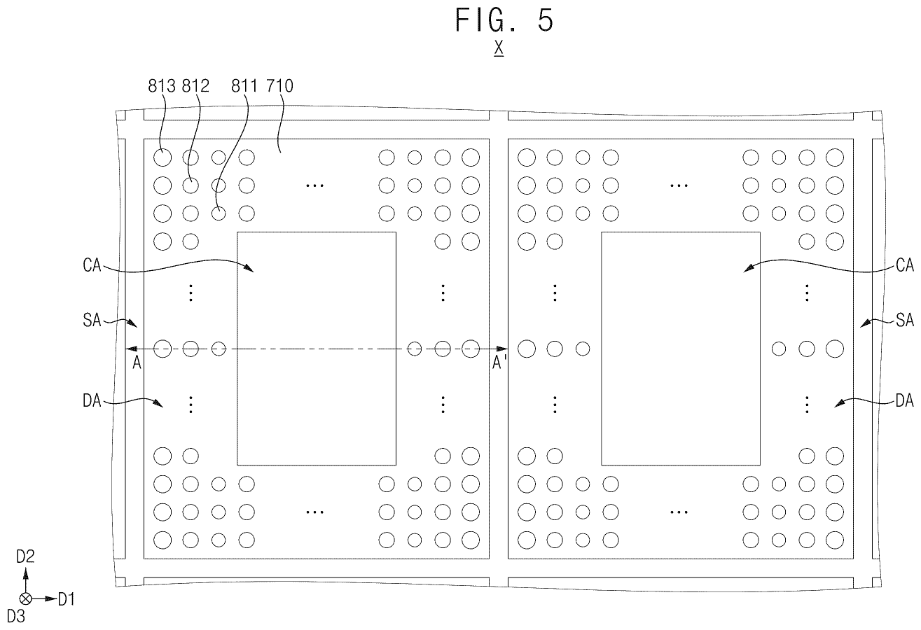

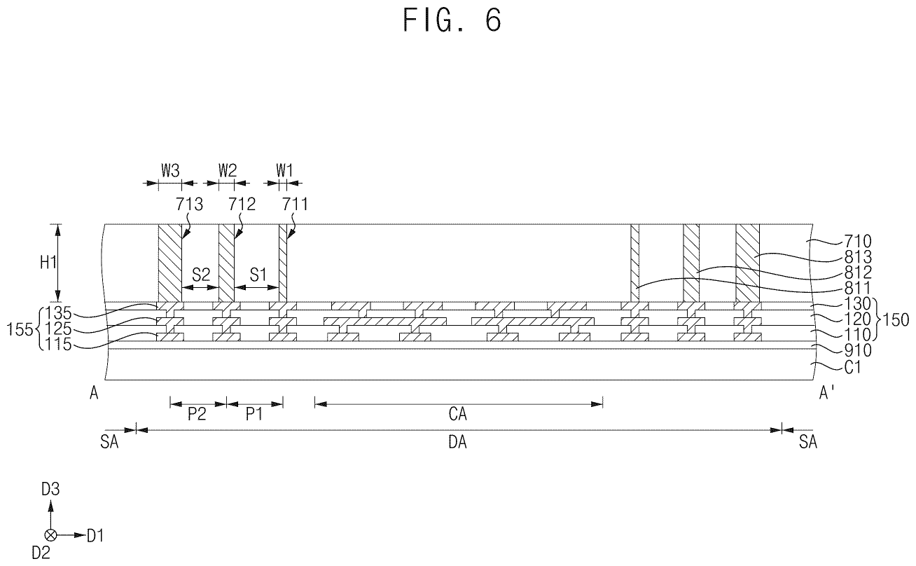

Particularly, FIGS. 4 and 5 are the plan views, and FIGS. 6 to 9 are cross-sectional views taken along lines A-A′ of corresponding plan views, respectively. FIG. 5 is a plan view of region X of FIG. 4.

Referring to FIGS. 4 to 6, a first temporary bonding layer 910 may be attached to a first carrier substrate C1, and a first RDL 150 may be formed on the first temporary bonding layer 910.

In some implementations, the first carrier substrate C1 may include a plurality of die regions DA and a scribe lane region SA surrounding the die region DA. Additionally, each of the die regions DA may include a chip region CA on which a semiconductor chip may be mounted. In some implementations, the chip region CA may be located at a central portion of each of the die regions DA and may have a rectangular shape in a plan view.

The first carrier substrate C1 may include, for example, a non-metal plate, a metal plate, a silicon substrate, a glass substrate, etc. The first temporary bonding layer 910 may include a material losing adhesion by an irradiation of light or heating or a release tape.

In some implementations, the first RDL 150 may include insulating interlayers stacked in the vertical direction and a first redistribution wiring structure 155 in the insulating interlayers, and the first redistribution wiring structure 155 may include, for example, wirings, vias, contact plugs and conductive pads.

FIG. 6 shows that the first RDL 150 includes first to third insulation layers 110, 120, and 130 sequentially stacked in the vertical direction, and the first redistribution wiring structure 155 includes a first conductive pad 115, a first redistribution wiring 125 and a second redistribution wiring 135.

For example, the first RDL 150 may be formed by following processes.

A first conductive pad 115 may be formed on the first temporary bonding layer 910, the first insulation layer 110 may be formed on the first temporary bonding layer 910 to cover the first conductive pad 115, and the first insulation layer 410 may be partially removed to form a first hole at least partially exposing an upper surface of the first conductive pad 115.

A first seed layer may be formed on an upper surface of the first insulation layer 410, a sidewall of the first hole and the exposed upper surface of the first conductive pad 115 by the first hole, an electroplating process or an electroless plating process may be performed to form a first redistribution wiring layer on the first seed layer, the first redistribution wiring layer may be patterned to form a first redistribution wiring 125, and a portion of the first seed layer not covered by the first redistribution wiring 125 may be removed. The first redistribution wiring 125 may contact the upper surface of the first conductive pad 115 through the first hole, and a portion of the first redistribution wiring 125 may serve as a second conductive pad.

A second insulation layer 120 may be formed on the first insulation layer 110 to cover the first redistribution wiring 125, the second insulation layer 120 may be partially removed to form a second hole exposing an upper surface of the second conductive pad, a second seed layer may be formed on an upper surface of the second insulation layer 120, a sidewall of the second hole and the exposed upper surface of the second conductive pad by the second hole, a second redistribution wiring layer may be formed on the second seed layer by an electroplating process or an electroless plating process, the second redistribution wiring layer may be patterned to form a second redistribution wiring 135, and a portion of the second seed layer not covered by the second redistribution wiring 135 may be removed. The second redistribution wiring 135 may contact the upper surface of the first redistribution wiring 125 through the second hole.

A third insulation layer 130 may be formed on the second insulation layer 120 to cover the second redistribution wiring 135, and a planarization process may be performed on the third insulation layer 130 until an upper surface of the second redistribution wiring 135 is exposed. Thus, the third insulation layer 130 may cover a sidewall of the second redistribution wiring 135. A portion of the second redistribution wiring 135 may serve as a third conductive pad. In some implementations, a plurality of third conductive pads may be spaced apart from each other in the horizontal direction.

A first photoresist layer having a first height H1 in the vertical direction from an upper surface of the first RDL 150 may be formed on the first RDL 150, an exposure process and a developing process may be performed on the first photoresist layer to form a first photoresist pattern 710 having first to third openings 711, 712 and 713 exposing upper surfaces of portions of the third conductive pads, respectively, and an electroplating process or an electroless plating process may be performed to form first to third conductive posts 811, 812 and 813 in the first to third openings 711, 712 and 713, respectively.

In some implementations, each of the first to third openings 711, 712, and 713 may extend in the vertical direction, and may have a width in the horizontal direction substantially constant in the vertical direction. The first to third openings 711, 712, and 713 may have first to third widths W1, W2, and W3, respectively, in the horizontal direction. The third width W3 may be greater than the second width W2, and the second width W2 may be greater than the first width W1.

In some implementations, a plurality of first conductive posts 811 may be arranged in a rectangular ring shape surrounding the chip region CA in a plan view, a plurality of second conductive posts 812 may be arranged in a rectangular ring shape surrounding the first conductive posts 811 in a plan view, and a plurality of third conductive posts 813 may be arranged in a rectangular ring shape surrounding the second conductive posts 812 in a plan view. Thus, the first conductive posts 811 may be closer to the chip region CA than the second conductive posts 812, and the second conductive posts 812 may be closer to the chip region CA than the third conductive posts 813.

The first to third openings 711, 712, and 713 may be formed between the chip regions CA disposed in each of the die regions DA. Thus, during the electroplating process or the electroless plating process for forming the first to third conductive posts 811, 812, and 813, the first openings 711 proximal to the chip region CA may be disposed at a relatively sparse area, while the third openings 713 distal to the chip region CA may be disposed at a relatively dense area, so that the first conductive posts 811 that may be formed in the first openings 711, respectively, may be formed at a speed less than a speed of the third conductive posts 813 that may be formed in the third openings 713, respectively.

If the horizontal widths of the first to third openings 711, 712, and 713 are the same, upper surfaces of the first to third conductive posts 811, 812, and 813 may not be the same. That is, the upper surface of the first conductive post 811, which may be formed at a relatively low speed, may be lower than the upper surface of the third conductive post 813, which may be formed at a relatively high speed.

However, in some implementations, the first to third openings 711, 712 and 713 may have the first to third widths W1, W2 and W3, respectively, that may have smaller values in this order, so that the speed difference of the formation of the first to third conductive posts 811, 812 and 813 may be neutralized. As a result, the upper surfaces of the first to third conductive posts 811, 812 and 813 that may be formed in the first to third openings 711, 712 and 713, respectively, may be formed at substantially the same height, that is, at the first height H1.

In some implementations, a first pitch P1 in the horizontal direction between centers of the first and second conductive posts 811 and 812 may be substantially the same as a second pitch P2 in the horizontal direction between centers of the second and third conductive posts 812 and 813. In some implementations, a first distance S1 in the horizontal direction between the first and second conductive posts 811 and 812 may be greater than a second distance S2 in the horizontal direction between the second and third conductive posts 812 and 813.

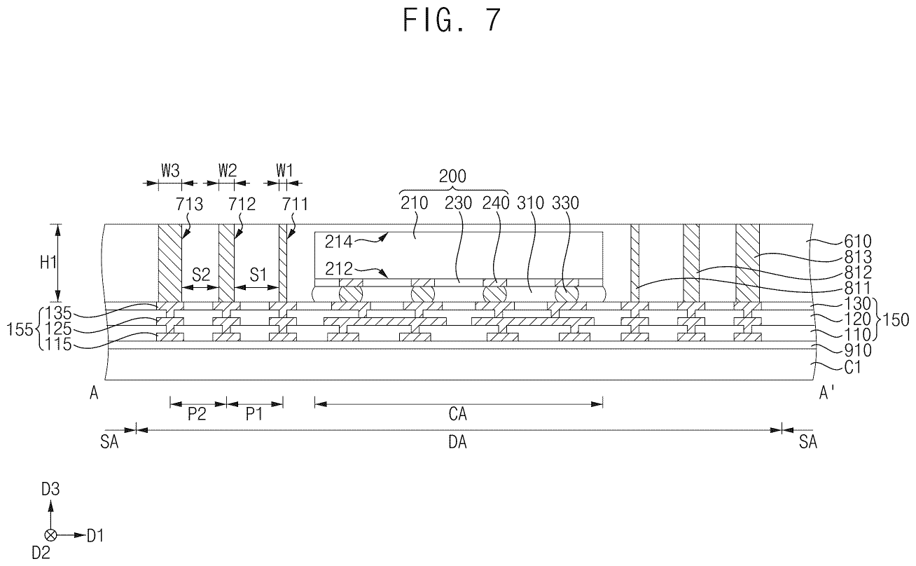

Referring to FIG. 7, the first photoresist pattern 710 may be removed by, for example, an ashing process and/or a stripping process.

A first semiconductor chip 200 may be mounted on and bonded with the first RDL 150 by, for example, a TCB process. However, the present disclosure is not limited thereto, and the first semiconductor chip 200 may be mounted on and bonded with the first RDL 150 by, for example, an HCB process.

In some implementations, the first semiconductor chip 200 may include a first substrate 210 having first and second surfaces 212 and 214 opposite to each other in the vertical direction and a first insulating interlayer and a second insulating interlayer 230 sequentially stacked in the vertical direction on the first surface 212 of the first substrate 210.

The first semiconductor chip 200 may be bonded with the first RDL 150 by the TCB process, as follows.

A third seed layer may be formed on an upper surface of the second insulation interlayer 230 of the first semiconductor chip 200, and a second photoresist pattern having a third hole overlapping in the vertical direction a portion of the first wiring structure 240 on the second insulating interlayer 230. For example, a conductive pad may be formed. An electroplating process or an electroless plating process may be performed to form a first conductive pattern on a portion of the third seed layer in the third hole. For example, an ashing process and/or a stripping process may be performed to remove the second photoresist pattern to partially expose the third seed layer, and the exposed portion of the third seed layer may be removed.

A third photoresist layer may be formed on the second insulating interlayer 230 to cover the first conductive pattern, the third photoresist layer may be patterned to form a third photoresist pattern having a fourth hole exposing an upper surface of the first conductive pattern, an electroplating process or an electroless plating process may be performed to form a preliminary second conductive pattern in the fourth hole, the third photoresist pattern may be removed, and a reflow process may be performed to convert the preliminary second conductive pattern into a second conductive pattern.

Thus, a second conductive connection member 330 including the first and second conductive patterns sequentially stacked in the vertical direction may be formed.

A first bonding layer 310 may be formed on the second insulating interlayer 230 to cover the second conductive connection member 330, the first semiconductor chip 200 may be overturned so that the second surface 214 may face upwardly, the first bonding layer 310 attached to the first semiconductor chip 200 may contact the upper surface of the first RDL 150 so that the first semiconductor chip 200 may be mounted on the first RDL 150. The first bonding layer 310 may include a non-conductive film (NCF), for example, thermosetting resin.

The first semiconductor chip 200 may be bonded with the first RDL 150 by a thermal compression process at a temperature of equal to or less than about 400° C. In the thermal compression process, the NCF of the first bonding layer 310 may be melted to become fluid and may flow between each of the first semiconductor chips 200 and the first RDL 150. The NCF may flow and be cured between the first semiconductor chip 200 and the first RDL 150 and may fill a space between the first semiconductor chip 200 and the first RDL 150. A portion of the cured first bonding layer 310 may protrude in the horizontal direction from a sidewall of the first semiconductor chip 200.

By the thermal compression process, the second conductive connection member 330 may be bonded with the third conductive pad in the first RDL 150.

A first mold layer may be formed on the first RDL 150 to cover the first semiconductor chip 200, the first bonding layer 310 and the first to third conductive posts 811, 812, and 813, and a planarization process, for example, a chemical mechanical polishing (CMP) process may be performed on the first mold layer until upper surfaces of the first to third conductive posts 811, 812, and 813 are exposed to form a first mold 610.

As illustrated above, the upper surfaces of the first to third conductive posts 811, 812, and 813 are substantially coplanar with each other, and thus none of the upper surfaces of the first to third conductive posts 811, 812, and 813 are not exposed by the planarization process, and all of the upper surfaces of the first to third conductive posts 811, 812, and 813 are be exposed.

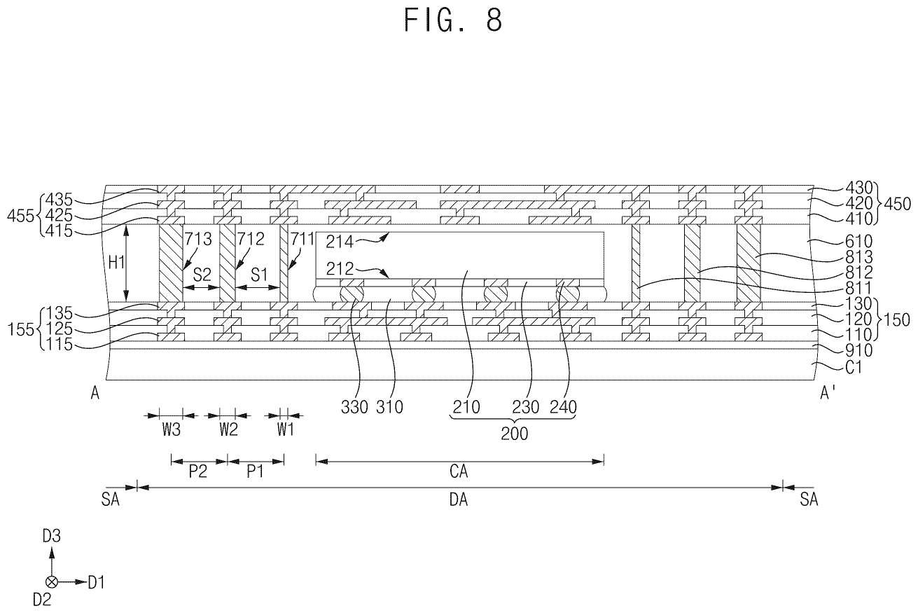

Referring to FIG. 8, a second RDL 450 may be formed on the first mold 610 and the first to third conductive posts 811, 812 and 813.

In some implementations, the second RDL 450 may include insulation layers and a second redistribution wiring structure 455 in the insulation layers, and the second redistribution wiring structure 455 may include, for example, redistribution wirings, vias, contact plugs, conductive pads, etc.

FIG. 8 shows that the second RDL 450 includes fourth, fifth and sixth insulation layers 410, 420, and 430 sequentially stacked in the vertical direction, and the second redistribution wiring structure 455 includes a fourth conductive pad 415, a third redistribution wiring 425 and a fourth redistribution wiring 435 sequentially stacked, however, the present disclosure is not limited thereto. Portions of the third and fourth redistribution wirings 425 and 435 may serve as fifth and sixth conductive pads, respectively.

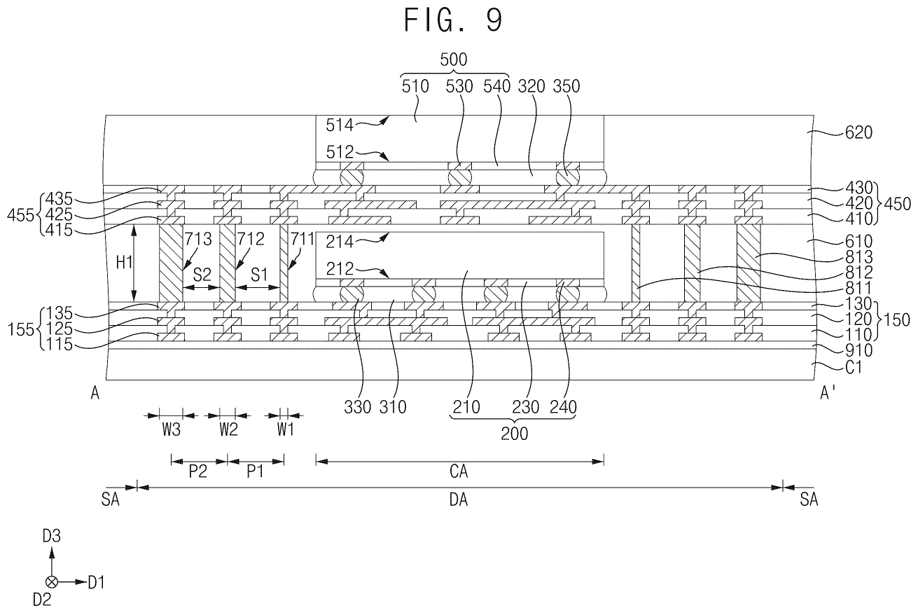

Referring to FIG. 9, a second semiconductor chip 500 may be mounted on and bonded with the second RDL 450 by, for example, a TCB process.

However, the present disclosure is not limited thereto, and the second semiconductor chip 500 may be bonded with the second RDL 450 by, an HCB process.

In some implementations, the second semiconductor chip 500 may include a second substrate 510 having first and second surfaces 512 and 514 opposite to each other in the vertical direction, and a third insulating interlayer and a fourth insulating interlayer 530 sequentially stacked in the vertical direction on the first surface 512 of the second substrate 510.

As the second semiconductor chip 500 is bonded with the second RDL 450 by a TCB process, a third conductive connection member 350 and a second bonding layer 320 covering the third conductive connection member 350 may be formed between the sixth conductive pad of the second RDL 450 and the second wiring structure 540 in the fourth insulating interlayer 530 of the second semiconductor chip 500.

A second mold layer may be formed on the second RDL 450 to cover the second semiconductor chip 500 and the second bonding layer 320, and a planarization process, for example, a CMP process may be performed on the second mold layer until an upper surface of the second semiconductor chip 500 is exposed to form a second mold 620.

Referring back to FIGS. 1 to 3, a second temporary bonding layer and a second carrier substrate may be attached to the second mold 620 and the second semiconductor chip 500, a structure including the first and second semiconductor chips 200 and 500, and the second carrier substrate may be overturned, the first temporary bonding layer 910 may be separated from the first RDL 150 so that the first carrier substrate C1 may be removed, a first conductive connection member 990 may be formed on the first RDL 150 to contact the first conductive pad 115, and the second carrier substrate may be cut along the scribe lane region SA by, for example, a sawing process to be singulated into a plurality of second carrier substrates.

During the sawing process, the first and second molds 610 and 620 stacked in the vertical direction on the second carrier substrate may also be cut to cover sidewalls of the first and second semiconductor chips 200 and 500 on each of the singulated second carrier substrates.

The second temporary bonding layer may be separated from the second mold 620 and the second semiconductor chip 500 to remove the second carrier substrate to complete the manufacturing the semiconductor package.

As illustrated above, in a plan view, the first to third openings 711, 712, and 713 arranged in a rectangular ring shape surrounding the chip region CA on which the first semiconductor chip 200 is mounted may have the first to third widths W1, W2, and W3 that may have smaller values in this order, which means that volumes of the first to third openings 711, 712, and 713 have smaller values in this order. Thus, during the electroplating process or the electroless plating process, the upper surfaces of the first to third conductive posts 811, 812, and 813 that may be formed in the first to third openings 711, 712, and 713, respectively, at lower speeds in this order, may be substantially coplanar with each other.

Accordingly, when the first mold layer is formed on the first RDL 150 to cover the first to third conductive posts 811, 812, and 813 and the planarization process is performed on the first mold layer, a phenomenon in which some of the upper surfaces of the first to third conductive posts 811, 812, and 813 are not exposed may be prevented.

In some implementations, three openings, that is, the first to third openings 711, 712 and 713 may be formed and the first to third conductive posts 811, 812 and 813 may be formed in the first to third openings 711, 712 and 713, respectively. However, the present disclosure is not limited thereto, and more or less than three openings may be formed to surround the chip region CA in a rectangular ring shape, and conductive posts may be formed in the openings, respectively. Widths and volumes of the openings may have smaller values as the openings are closer to the chip region CA.

Hereinafter, the present disclosure in which the widths and volumes of the openings or the widths and volumes of the conductive posts therein may have smaller values as the openings or the conductive posts are closer to the chip region CA or the first semiconductor chip 200 is illustrated with some examples.

In some implementations, the semiconductor package may be a fan out wafer level package (FOWLP). However, the present disclosure is not limited thereto, and may be, for example, a fan out panel level package (FOPLP).

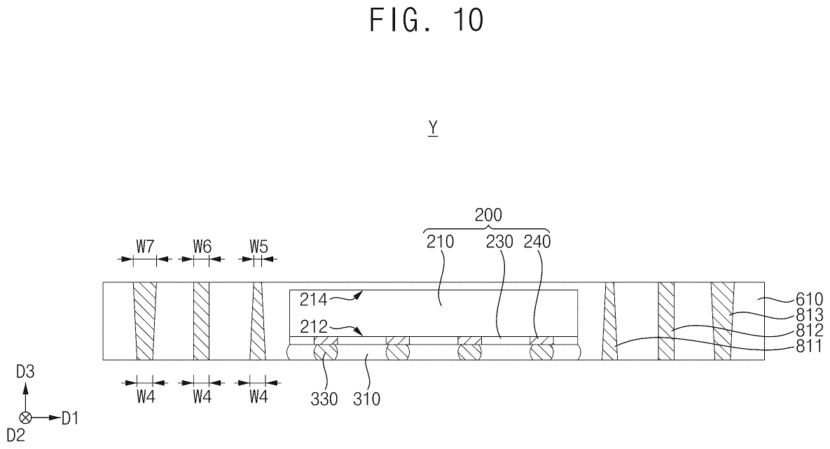

Each of semiconductor packages illustrated with reference to FIGS. 10 to 18 may be substantially the same as or similar to that of FIGS. 1 to 3, except for the shapes and sizes of the conductive posts, and thus repeated explanations are omitted herein.

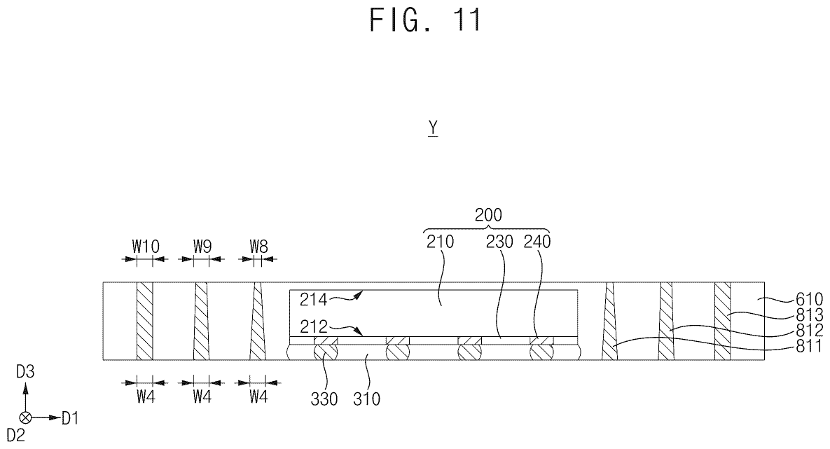

FIGS. 10 and 11 are cross-sectional views illustrating examples of semiconductor packages, which may correspond to FIG. 2.

Referring to FIG. 10, a lower end of each of the first to third conductive posts 811, 812 and 813 has a fourth width W4 in the horizontal direction, and upper ends of the first to third conductive posts 811, 812 and 813 have fifth to seventh widths W5, W6 and W7 in the horizontal direction.

In some implementations, the sixth width W6 may be substantially the same as the fourth width W4, and thus a width in the horizontal direction of the second conductive post 812 may be substantially constant in the vertical direction.

In some implementations, a width in the horizontal direction of the first conductive post 811 may gradually decrease from a bottom toward a top thereof in the vertical direction, and a width in the horizontal direction of the third conductive post 813 may gradually increase from a bottom toward a top thereof in the vertical direction. Thus, the fifth width W5 may be smaller than the fourth width W4, and the seventh width W7 may be greater than the fourth width W4.

As a result, the fifth to seventh widths W5, W6, and W7 of the upper ends of the first to third conductive posts 811, 812, and 813 may have smaller values in this order, and volumes of the first to third conductive posts 811, 812, and 813 may have smaller values in this order.

Referring to FIG. 11, the lower ends of each of the first to third conductive posts 811, 812 and 813 may have the fourth width W4 in the horizontal direction, and the upper ends of each of the first to third conductive posts 811, 812 and 813 may have eighth to tenth widths W8, W9 and W10 in the horizontal direction.

In some implementations, the tenth width W10 may be substantially the same as the fourth width W4, and thus a width in the horizontal direction of the third conductive post 813 may be substantially constant in the vertical direction.

In some implementations, a width in the horizontal direction of each of the first and second conductive posts 811 and 812 may gradually decrease from a bottom toward a top thereof in the vertical direction, and thus each of the eighth and ninth widths W8 and W9 may be smaller than the fourth width W4. In some implementations, a slope of a sidewall of the first conductive post 811 may be smaller than a slope of a sidewall of the second conductive post 812.

As a result, the eighth to tenth widths W8, W9 and W10 of the upper ends of the first to third conductive posts 811, 812 and 813 may have smaller values in this order, and volumes of the first to third conductive posts 811, 812 and 813 may have smaller values in this order.

FIG. 10 shows that the horizontal width of the first conductive post 811 gradually decreases from a bottom toward a top thereof in the vertical direction and the horizontal width of the third conductive post 813 gradually increases from a bottom toward a top thereof in the vertical direction. FIG. 11 shows that the horizontal width of the first conductive post 811 gradually decreases from a bottom toward a top thereof in the vertical direction and the horizontal width of the third conductive post 813 are substantially constant from a bottom toward a top thereof in the vertical direction. However, the present disclosure is not limited thereto.

In some implementations, the horizontal width of each of the first and third conductive posts 811 and 813 may gradually decrease from a bottom toward a top thereof in the vertical direction, or the horizontal width of each of the first and third conductive posts 811 and 813 may gradually increase from a bottom toward a top thereof in the vertical direction. However, the volume of the first conductive post 811 may be smaller than the volume of the third conductive post 813.

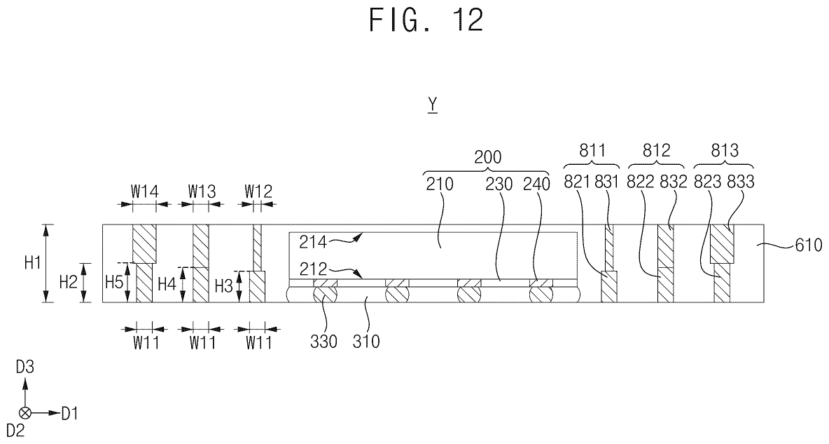

FIG. 12 is a cross-sectional view illustrating examples of semiconductor packages, which may correspond to FIG. 2.

Referring to FIG. 12, each of the first to third conductive posts 811, 812 and 813 includes a lower portion and an upper portion stacked in the vertical direction, and a horizontal width in each of the lower and upper portions may be substantially constant in the vertical direction.

That is, the first conductive post 811 includes a first lower portion 821 and a first upper portion 831, the second conductive post 812 includes a second lower portion 822 and a second upper portion 832, and the third conductive post 813 includes a third lower portion 823 and a third upper portion 833.

In some implementations, each of the first to third lower portions 821, 822, and 823 of the first to third conductive posts 811, 812, and 813, respectively, may have an eleventh width W11 in the horizontal direction, and the first to third upper portions 831, 832, and 833 of the first to third conductive posts 811, 812, and 813, respectively, may have twelfth to fourteenth widths W12, W13, and W14 in the horizontal direction.

In some implementations, the thirteenth width W13 may be substantially the same as the eleventh width W11, and thus the lower and upper portions 822 and 832 of the second conductive post 812 may have substantially the same width in the horizontal direction.

In some implementations, the twelfth width W12 may be smaller than the eleventh width W11, and the fourteenth width W14 may be greater than the eleventh width W11. Thus, the first upper portion 831 of the first conductive post 811 may have a width smaller than that of the first lower portion 821 thereof, and the third upper portion 833 of the third conductive post 813 may have a width greater than that of the third lower portion 823 thereof. Additionally, the twelfth to fourteenth widths W12, W13 and W14 of the first to third upper portions 831, 832 and 833 of the first to third conductive posts 811, 812 and 813, respectively, may have smaller values in this order.

In some implementations, upper surfaces of the first to third lower portions 821, 822, and 823 of the first to third conductive posts 811, 812, and 813, respectively, may have third to fifth heights H3, H4, and H5, respectively, from the upper surface of the first RDL 150, which may have smaller values in this order. Each of upper surfaces of the first to third upper portions 831, 832, and 833 of the first to third conductive posts 811, 812, and 813, respectively, may have substantially the same height, that is, the first height H1 of the upper surface of the first mold 610 from the upper surface of the first RDL 150.

Thus, thicknesses of the first to third lower portions 821, 822, and 823 of the first to third conductive posts 811, 812, and 813, respectively, may have smaller values in this order, and thicknesses of the first to third upper portions 831, 832, and 833 of the first to third conductive posts 811, 812, and 813, respectively, may have greater values in this order.

In some implementations, volumes of the first to third lower portions 821, 822, and 823 of the first to third conductive posts 811, 812, and 813, respectively, may have smaller values in this order, and volumes of the first to third upper portions 831, 832, and 833 of the first to third conductive posts 811, 812, and 813, respectively, may have smaller values in this order.

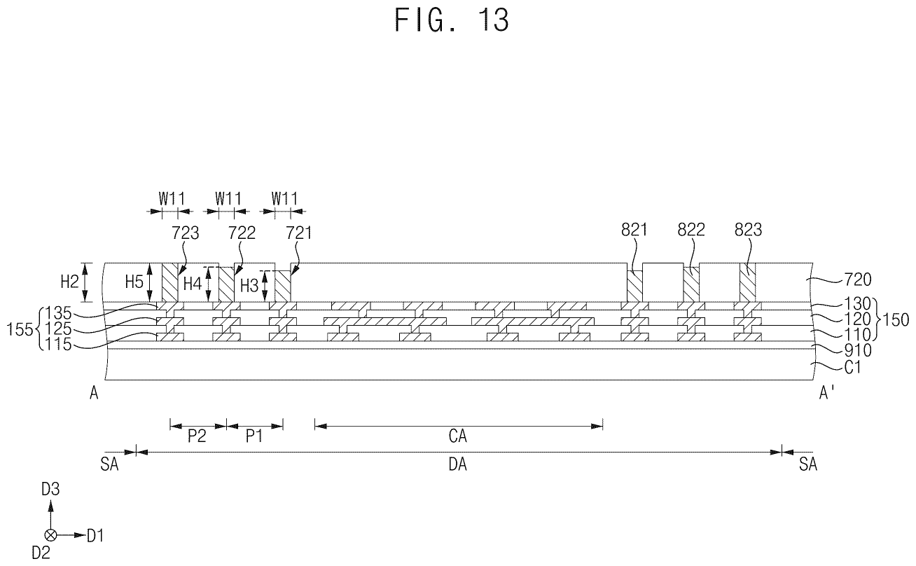

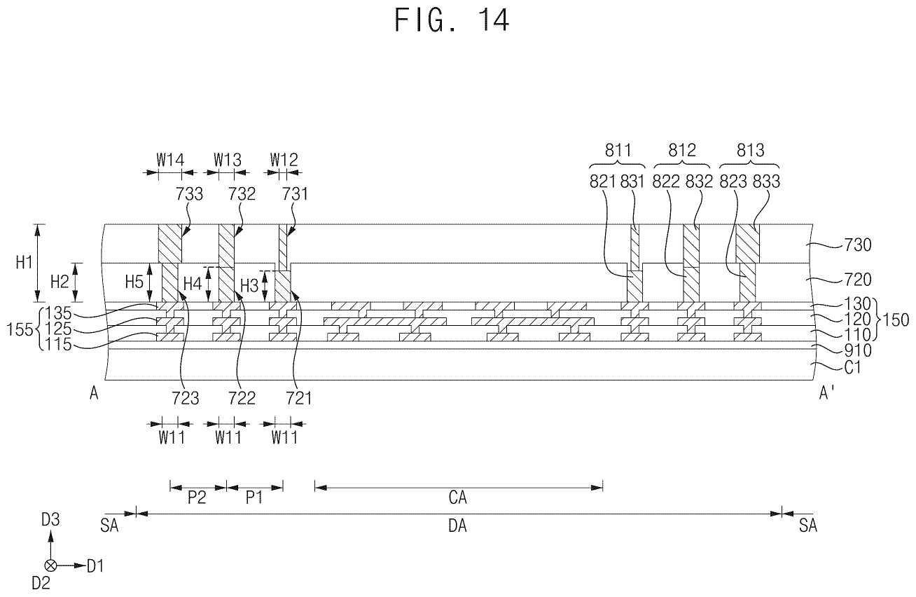

FIGS. 13 and 14 are cross-sectional views illustrating an example of a method of manufacturing a semiconductor package, which may correspond to FIG. 6. This method may include processes substantially the same as or similar to those illustrated with respect to FIGS. 4 to 9 and FIGS. 1 to 3, and thus repeated explanations thereof are omitted herein.

Referring to FIG. 13, processes substantially the same as or similar to those illustrated with respect to FIGS. 4 to 6 may be performed to form first to third lower portions 821, 822, 823 of the first to third conductive posts 811, 812, and 813 on the first RDL 150.

Particularly, a fourth photoresist layer having a second height H2 in the vertical direction from an upper surface of the first RDL 150 may be formed on the first RDL 150, an exposure process and a developing process may be performed on the fourth photoresist layer to form a fourth photoresist pattern 720 having fourth to sixth openings 721, 722, and 723 exposing upper surfaces of portions of the third conductive pads, respectively, and an electroplating process or an electroless plating process may be performed to form the first to third lower portions 821, 822, 823 in the fourth to sixth openings 721, 722, and 723, respectively.

Each of the fourth to sixth openings 721, 722, and 723 may have an eleventh width W11 in the horizontal direction, and upper surfaces of the first to third lower portions 821, 822 and 823 in the fourth to sixth openings 721, 722, and 723, respectively, may have third to fifth heights H3, H4, and H5. The fourth to sixth openings 721, 722, and 723 may have substantially the same width in the horizontal direction, and thus, due to the difference between speeds of formation of the first to third lower portions 821, 822, and 823, the third to fifth heights H3, H4, and H5 may have smaller values in this order. In some implementations, the fifth height H5 may be substantially the same as the second height H2, and the third and fourth heights H3 and H4 may be smaller than the second height H2.

Referring to FIG. 14, a fifth photoresist layer having the first height H1 in the vertical direction from the upper surface of the first RDL 150 may be formed on the fourth photoresist pattern 720 and the first to third lower portions 821, 822, and 823 of the first to third conductive posts 811, 812, and 813, respectively, an exposure process and a developing process may be performed on the fifth photoresist layer to form a fifth photoresist pattern 730 having seventh to ninth openings 731, 732, and 733 exposing upper surfaces of the first to third lower portions 821, 822, and 823, respectively, and an electroplating process or an electroless plating process may be performed to form the first to third upper portions 831, 832, 833 in the seventh to ninth openings 731, 732, and 733, respectively.

The seventh to ninth openings 731, 732, and 733 may have twelfth to fourteenth widths W12, W13, and W14 in the horizontal direction, which may have smaller values in this order. Thus, even though speeds of formation of the first to third upper portions 831, 832, and 833 in the seventh to ninth openings 731, 732, and 733, respectively, are different from each other, upper surfaces of the first to third upper portions 831, 832, and 833 in the seventh to ninth openings 731, 732, and 733, respectively, may have substantially the same height, that is, the first height H1 from the upper surface of the first RDL 150.

In some implementations, a thickness in the vertical direction of the first upper portion 831 may be greater than a thickness in the vertical direction of the second upper portion 832, and the thickness in the vertical direction of the second upper portion 832 may be greater than a thickness in the vertical direction of the third upper portion 833. In some implementations, the thickness in the vertical direction of the third upper portion 833 may be substantially the same as a thickness in the vertical direction of the fifth photoresist pattern 730.

Processes substantially the same as or similar to those illustrated with respect to FIGS. 7 to 9 and FIGS. 1 to 3 may be performed to complete the manufacturing the semiconductor package.

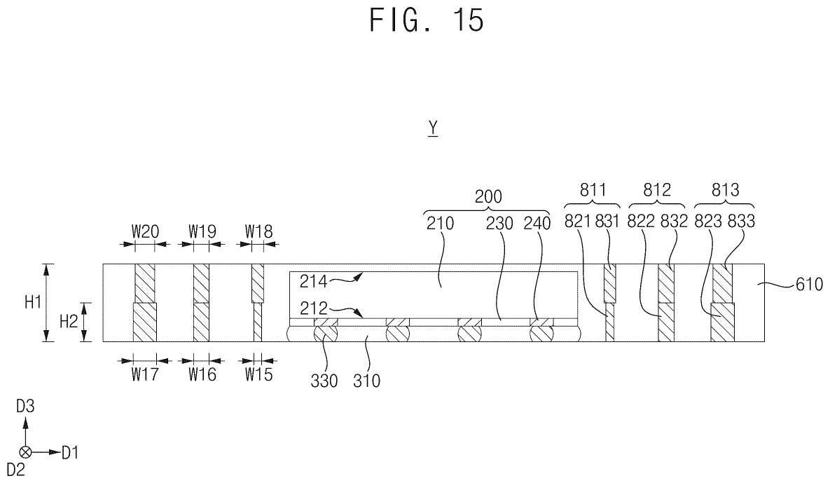

FIG. 15 is a cross-sectional view illustrating an example of a semiconductor package, which may correspond to FIG. 12.

Referring to FIG. 15, the first to third lower portions 821, 822, and 823 of the first to third conductive posts 811, 812, and 813, respectively, may have fifteenth to seventeenth widths W15, W16, and W17, respectively, in the horizontal direction, which may have smaller values in this order. Additionally, the upper surfaces of the first to third lower portions 821, 822, and 823 of the first to third conductive posts 811, 812, and 813, respectively, may have the second height H2.

The first to third upper portions 831, 832 and 833 of the first to third conductive posts 811, 812 and 813, respectively, may have eighteenth to twentieth widths W18, W19 and W20 in the horizontal direction, which may have smaller values in this order. Additionally, the upper surfaces of the first to third upper portions 831, 832 and 833 of the first to third conductive posts 811, 812 and 813, respectively, may have the first height H1.

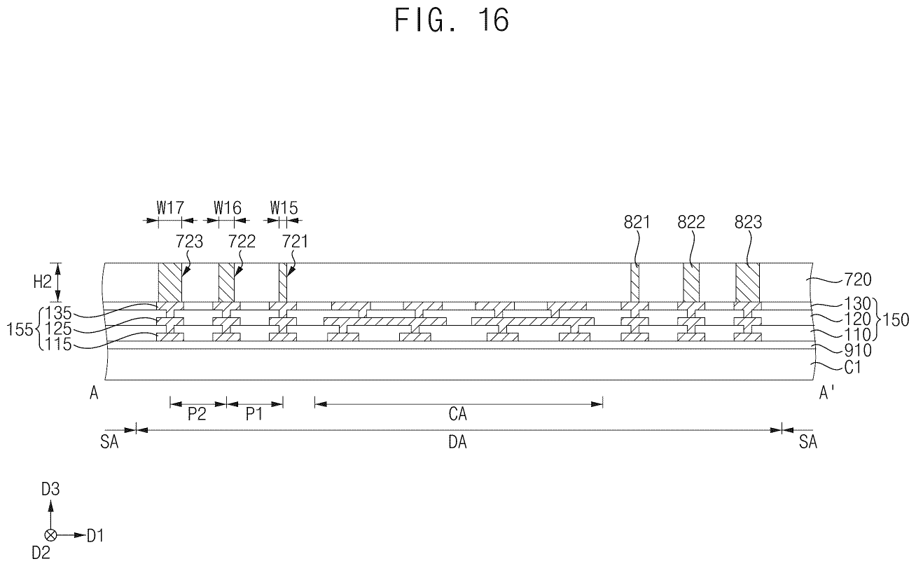

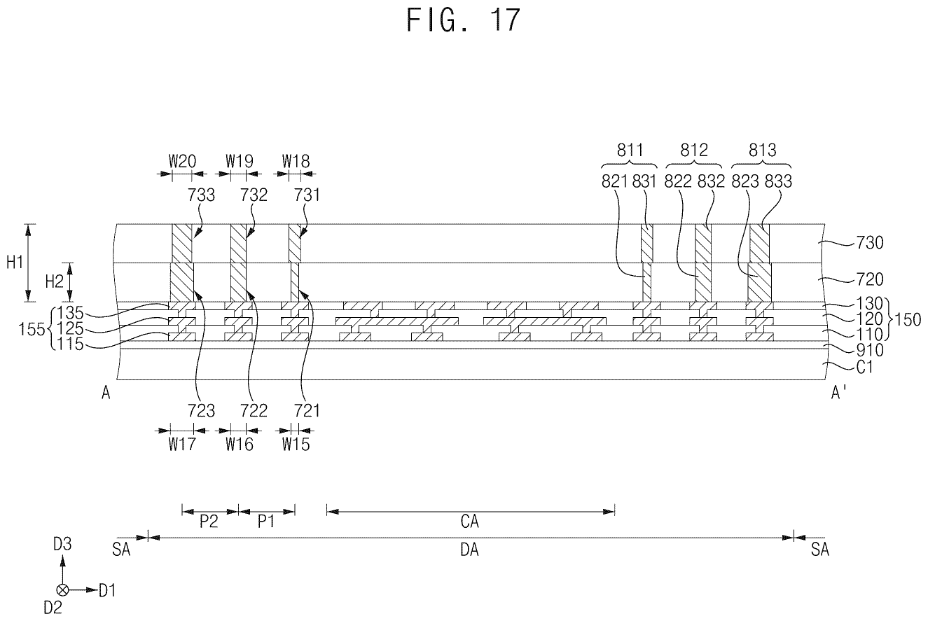

As illustrated below with reference to FIGS. 16 and 17, the fourth to sixth openings 721, 722, and 723 in which the first to third lower portions 821, 822, and 823 may be formed may have smaller widths in this order. Thus the difference between the speeds of formation of the first to third lower portions 821, 822, and 823 may be neutralized so that the upper surfaces of the first to third lower portions 821, 822, and 823 may have substantially the same height. Additionally, the seventh to ninth openings 731, 732, and 733 in which the first to third upper portions 831, 832, and 833 may be formed may have smaller widths in this order. Thus the difference between the speeds of formation of the first to third upper portions 831, 832, and 833 may be neutralized so that the upper surfaces of the first to third upper portions 831, 832, and 833 may have substantially the same height.

However, in some implementations, the nineteenth width W19 may be substantially the same as the sixteenth width W16, the eighteenth width W18 may be greater than the fifteenth width W15, and the twentieth width W20 may be smaller than the seventeenth width W17. That is, if only the eighteenth to twentieth widths W18, W19 and W20 of the seventh to ninth openings 731, 732, and 733 in which the first to third upper portions 831, 832, and 833 may be formed, respectively, have smaller values in this order, the eighteenth to twentieth widths W18, W19, and W20 may have various values regardless of the horizontal widths of the first to third lower portions 821, 822, and 823.

Thus, the first upper portion 831 may have a width smaller than that of the first lower portion 821 and the third upper portion 833 may have a width greater than that of the third lower portion in the semiconductor package of FIG. 12, while the first upper portion 831 may have a width greater than that of the first lower portion 821 and the third upper portion 833 may have a width smaller than that of the third lower portion in the semiconductor package of FIG. 15.

In some implementations, the first upper portion 831 may have a width smaller than that of the first lower portion 821 and the third upper portion 833 may have a width smaller than that of the third lower portion 823. Alternatively, the first upper portion 831 may have a width greater than that of the first lower portion 821 and the third upper portion 833 may have a width greater than that of the third lower portion 823.

That is, if only the first to third lower portions 821, 822, and 823 have smaller values in this order and the first to third upper portions 831, 832, and 833 have smaller values in this order according to the distance to the first semiconductor chip 200, the widths of the lower and upper portions of each of the first to third conductive posts 811, 812, and 813 may be substantially the same as or different from each other.

FIGS. 16 and 17 are cross-sectional views illustrating an example of a method of manufacturing a semiconductor package, which may correspond to FIGS. 13 and 14, respectively. This method may include processes substantially the same as or similar to those illustrated with respect to FIGS. 13 and 14 and FIG. 12, and thus repeated explanations thereof are omitted herein.

Referring to FIG. 16, processes substantially the same as or similar to those illustrated with respect to FIG. 13 may be performed to form the first to third lower portions 821, 822, and 823 of the first to third conductive posts 811, 812, and 813, respectively.

In some implementations, the fourth to sixth openings 721, 722 and 723 in the fourth photoresist pattern 720 may have the fifteenth to seventeenth widths W15, W16, and W17, respectively, which may have smaller values in this order. Additionally, each of the upper surfaces of the first to third lower portions 821, 822, and 823 in the fourth to sixth openings 721, 722, and 723 may have the second height H2.

That is, the fourth to sixth openings 721, 722, and 723 have smaller values in this order, and thus the speed difference between the formation of the first to third lower portions 821, 822, and 823 may be neutralized so that the upper surfaces of the first to third lower portions 821, 822, and 823 may have substantially the same height.

Referring to FIG. 17, processes substantially the same as or similar to those illustrated with respect to FIG. 14 may be performed to form the first to third upper portions 831, 832, and 833 of the first to third conductive posts 811, 812, and 813, respectively, in the fifth photoresist pattern 730.

In some implementations, the seventh to ninth openings 731, 732 and 733 in the fifth photoresist pattern 730 may have the eighteenth to twentieth widths W18, W19, and W20, respectively, in the horizontal direction, which may have smaller values in this order. Additionally, each of the upper surfaces of the first to third upper portions 831, 832 and 833 in the seventh to ninth openings 731, 732, and 733, respectively, may have the first height H1.

That is, the seventh to ninth openings 731, 732, and 733 may have smaller values in this order, and thus the speed difference between the formation of the first to third upper portions 831, 832, and 833 may be neutralized so that the upper surfaces of the first to third upper portions 831, 832, and 833 may have substantially the same height.

However, in some implementations, the nineteenth width W19 may be substantially the same as the sixteenth width W16, the eighteenth width W18 may be greater than the fifteenth width W15, and the twentieth width W20 may be smaller than the seventeenth width W17.

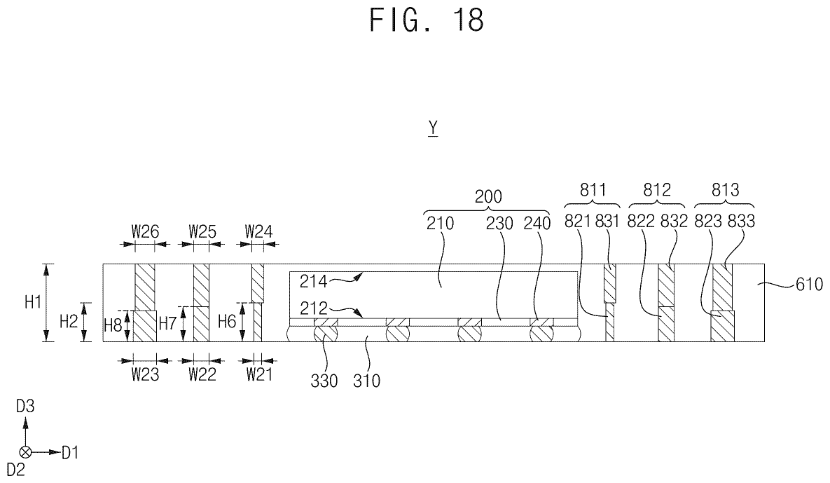

FIG. 18 is a cross-sectional view illustrating an example of a semiconductor package, which may correspond to FIG. 15.

Referring to FIG. 18, the first to third lower portions 821, 822, and 823 of the first to third conductive posts 811, 812, and 813, respectively, may have twenty-first to twenty-third widths W21, W22, and W23, respectively, in the horizontal direction, which may have smaller values in this order. Additionally, the upper surfaces of the first to third lower portions 821, 822, and 823 of the first to third conductive posts 811, 812, and 813, respectively, may have sixth to eighth heights H6, H7, and H8, respectively, which may have smaller values in this order.

The first to third upper portions 831, 832, and 833 of the first to third conductive posts 811, 812, and 813, respectively, may have twenty-fourth to twenty-sixth widths W24, W25 and W26, respectively, in the horizontal direction, which may have smaller values in this order. Additionally, each of the upper surfaces of the first to third upper portions 831, 832, and 833 of the first to third conductive posts 811, 812, and 813, respectively, may have the first height H1.

In some implementations, the fourth to sixth openings 721, 722 and 723 in which the first to third lower portions 821, 822, and 823 may be formed, respectively, may have smaller widths in this order, and thus the difference between the speeds of formation of the first to third lower portions 821, 822, and 823 may be neutralized. Further, if the difference between the widths of the fourth to sixth openings 721, 722, and 723 is large, the upper surfaces of the first to third lower portions 821, 822, and 823 may have greater values in this order, instead of having substantially the same value.

The seventh to ninth openings 731, 732, and 733 in which the first to third upper portions 831, 832, and 833 may be formed, respectively, may have smaller widths in this order, and thus the difference between the speeds of formation of the first to third upper portions 831, 832, and 833 may be neutralized so that the upper surfaces of the first to third upper portions 831, 832, and 833 may have substantially the same height.

In some implementations, distances between lower and upper ends of the seventh to ninth openings 731, 732, and 733 may have smaller values in this order, and thus width differences between the seventh to ninth openings 731, 732, and 733 in which the first to third upper portions 831, 832, and 833 may be formed, respectively, may be smaller than width differences between the fourth to sixth openings 721, 722, and 723 in which the first to third lower portions 821, 822, and 823 may be formed, respectively.

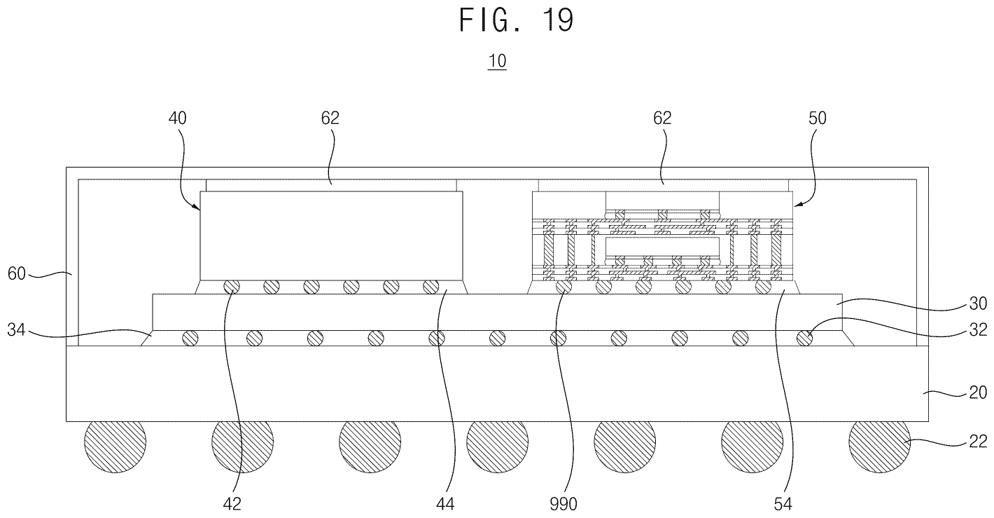

FIG. 19 is a cross-sectional view illustrating an example of an electronic device.

This electronic device may include the first semiconductor package 50 shown in FIGS. 1 to 3 as a second semiconductor device, e.g., in this example the first semiconductor package is first semiconductor device 40.

Referring to FIG. 19, an electronic device 10 may include a package substrate 20, an interposer 30, a first semiconductor device 40 and the second semiconductor device 50. The electronic device 10 may further include first, second and third underfill members 34, 44, and 54, a heat slug 60 and a heat dissipation member 62.

In some implementations, the electronic device 10 may be a memory module having a 2.5D, e.g., two dimensional though appearing three dimensional, package structure, and thus may include the interposer 30 for electrically connecting the first and second semiconductor devices 40 and 50 to each other.

In some implementations, the first semiconductor device 40 may include a logic device, and the second semiconductor device 50 may include a memory device. The logic device may be an application-specific integrated circuit (ASIC) chip including, for example, a central processing unit (CPU), a graphics processing unit (GPU), a micro-processor, a micro-controller, an application processor (AP), a digital signal processing core, etc. The memory device may be the first semiconductor device 50 of FIGS. 1 to 3.

In some implementations, the package substrate 20 may have an upper surface and a lower surface opposite to each other in the vertical direction. For example, the package substrate 20 may be a printed circuit board (PCB). The printed circuit board may be a multi-layer circuit board having various circuits therein.

The interposer 30 may be mounted on the package substrate 20 through a fifth conductive connection member 32. In some implementations, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 or electrically connected to the package substrate 20 through the fifth conductive connection member 32. The fifth conductive connection member 32 may include, for example, a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a TCB method. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through a sixth conductive connection member 42. For example, the sixth conductive connection member 42 may include, for example, a micro-bump.

Alternatively, the first semiconductor device 40 may be mounted on the interposer 30 by a wire bonding method, and in this case, the active surface of the first semiconductor device 40 may face upwardly.

The second semiconductor device 50 may be disposed on the interposer 30 and may be spaced apart from the first semiconductor device 40 in the horizontal direction. The second semiconductor device 50 may be mounted on and bonded with the interposer 30 by a TCB method. In this case, conductive pads of the second semiconductor device 50 may be electrically connected to conductive pads of the interposer 30 by the first conductive connection member 990.

Although a single first semiconductor device 40 and a single second semiconductor device 50 are disposed on the interposer 30, however, the present disclosure is not limited thereto, and a plurality of first semiconductor devices 40 and/or a plurality of second conductive devices 50 may be disposed on the interposer 30.

In some implementations, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44, and 54 may include a material having a relatively high fluidity to effectively fill a small space between the first and second semiconductor devices 40 and 50 and the interposer 30 and a small space between the interposer 30 and the package substrate 20. For example, each of the first and second underfill members 34, 44, and 54 may include an adhesive containing an epoxy material.

In some implementations, the heat slug 60 may cover the package substrate 20 to thermally contact the first and second semiconductor devices 40 and 50. The heat dissipation member 62 may be disposed on an upper surface of each of the first and second semiconductor devices 40 and 50, and may include, for example, thermal interface material (TIM). The heat slug 60 may thermally contact the first and second semiconductor devices 40 and 50 via the heat dissipation member 62.

A conductive pad may be formed at a lower portion of the package substrate 20, and a sixth conductive connection member 22 may be disposed beneath the conductive pad. In some implementations, a plurality of fourth conductive connection members 22 may be spaced apart from each other in the horizontal direction. The fourth conductive connection member 22 may be, for example, a solder ball. The electronic device 10 may be mounted on a module board via the sixth conductive connection members 42 to form a memory module.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example embodiments and is not to be construed as limiting thereof. Although a few example embodiments have been described, those skilled in the art will readily appreciate that many modifications are possible. In some implementations without materially departing from the novel teachings and advantages of the present invention. Accordingly, all such modifications are intended to be included within the scope of example embodiments as defined in the claims.

What is claimed is:

1. A semiconductor package comprising:
a first redistribution layer (RDL) comprising a first redistribution wiring structure;
a first semiconductor chip mounted on the first RDL;
a first mold on the first RDL, the first mold covering the first semiconductor chip;
a second RDL on the first mold, the second RDL comprising a second redistribution wiring structure;
a first conductive post extending through the first mold between the first and second RDLs and contacting the first and second redistribution wiring structures, wherein the first conductive post are spaced apart from the first semiconductor chip in a horizontal direction by a first distance; and
a second conductive post extending through the first mold between the first and second RDLs and contacting the first and second redistribution wiring structures, wherein the second conductive post are spaced apart from the first semiconductor chip in the horizontal direction by a second distance that is greater than the first distance,
wherein a volume of the first conductive post is smaller than a volume of the second conductive post.

2. The semiconductor package of claim 1, wherein an upper surface of the first conductive post is coplanar with an upper surface of the second conductive post, and
wherein a width in the horizontal direction of the first conductive post is smaller than a width in the horizontal direction of the second conductive post.

3. The semiconductor package of claim 2, wherein the width in the horizontal direction of the first conductive post is constant in a vertical direction, and the width in the horizontal direction of the second conductive post is constant in the vertical direction.

4. The semiconductor package of claim 1, wherein a width in the horizontal direction of the first conductive post decreases from a bottom of the first conductive post toward a top of the first conductive post in a vertical direction, and
wherein the width in the horizontal direction of the second conductive post increases from a bottom of second conductive post toward a top of second conductive post in the vertical direction.

5. The semiconductor package of claim 1, wherein a width in the horizontal direction of the first conductive post decreases from a bottom of the first conductive post toward a top of the first conductive post in a vertical direction, and
wherein the width in the horizontal direction of the second conductive post is constant in the vertical direction.

6. The semiconductor package of claim 1, wherein the first conductive post includes:
a first lower portion having a first width; and
a first upper portion contacting the first lower portion, the first upper portion having a second width smaller than the first width, and
wherein the second conductive post includes:
a second lower portion having a third width; and
a second upper portion contacting the second lower portion, the second upper portion having a fourth width greater than the third width.

7. The semiconductor package of claim 6, wherein the first width of the first lower portion of the first conductive post is the same as the third width of the second lower portion of the second conductive post.

8. The semiconductor package of claim 7, wherein an upper surface of the first lower portion of the first conductive post is lower than an upper surface of the second lower portion of the second conductive post.

9. The semiconductor package of claim 1, wherein the first conductive post includes:
a first lower portion having a first width; and
a first upper portion contacting the first lower portion, the first upper portion having a second width greater than the first width, and
wherein the second conductive post includes:
a second lower portion having a third width; and
a second upper portion contacting the second lower portion, the second upper portion having a fourth width smaller than the third width.

10. The semiconductor package of claim 9, wherein an upper surface of the first lower portion of the first conductive post is coplanar with an upper surface of the second lower portion of the second conductive post.

11. The semiconductor package of claim 10, wherein the first width of the first lower portion of the first conductive post is smaller than the third width of the second lower portion of the second conductive post.

12. The semiconductor package of claim 1, further comprising:
a second semiconductor chip on the second RDL; and
a second mold on the second RDL, the second mold covering the second semiconductor chip.

13. A semiconductor package comprising:
a first redistribution layer (RDL) comprising a first redistribution wiring structure;
a first semiconductor chip mounted on the first RDL;
a mold on the first RDL, the mold covering the first semiconductor chip;
a second RDL on the mold, the second RDL comprising a second redistribution wiring structure;
a first conductive post extending through the mold between the first and second RDLs and contacting the first and second redistribution wiring structures, wherein the first conductive post is spaced apart from the first semiconductor chip in a horizontal direction by a first distance, and the first conductive post including:
a first lower portion having a first width; and
a first upper portion contacting the first lower portion, the first upper portion having a second width smaller than the first width, and
a second conductive post extending through the mold between the first and second RDLs and contacting the first and second redistribution wiring structures, wherein the second conductive post is spaced apart from the first semiconductor chip in the horizontal direction by a second distance that is greater than the first distance, and the second conductive post including:
a second lower portion having a third width; and
a second upper portion contacting the second lower portion, the second upper portion having a fourth width greater than the third width.

14. The semiconductor package of claim 13, wherein the first width of the first lower portion of the first conductive post is the same as the third width of the second lower portion of the second conductive post.

15. The semiconductor package of claim 14, wherein an upper surface of the first lower portion of the first conductive post is lower than an upper surface of the second lower portion of the second conductive post.

16. The semiconductor package of claim 14, wherein a thickness in a vertical direction of the first upper portion of the first conductive post is greater than a thickness in the vertical direction of the second upper portion of the second conductive post.

17. The semiconductor package of claim 13, wherein widths in the horizontal direction of the first upper portion and the lower portions of the first conductive post are constant in a vertical direction, and
wherein widths in the horizontal direction of the second upper portion and the lower portions of the second conductive post are constant in the vertical direction.

18. A semiconductor package comprising:
a first redistribution layer (RDL) comprising a first redistribution wiring structure;
a conductive connection member beneath a lower surface of the first RDL;
a first semiconductor chip mounted on the first RDL;
a first mold on the first RDL, the first mold covering the first semiconductor chip;
a second RDL on the first mold, the second RDL comprising a second redistribution wiring structure;
a second semiconductor chip mounted on the second RDL;
a second mold on the second RDL, the second mold covering the second semiconductor chip;
first conductive posts each extending through the first mold between the first and second RDLs and contacting the first and second redistribution wiring structures, wherein the first conductive posts are arranged in a rectangular ring shape at a first distance from the first semiconductor chip in a horizontal direction in a plan view; and
second conductive posts each extending through the first mold between the first and second RDLs and contacting the first and second redistribution wiring structures, wherein the second conductive posts are arranged in a rectangular ring shape at a second distance from the first semiconductor chip in the horizontal direction, and the second distance being greater than the first distance,
wherein a volume of each of the first conductive posts is smaller than a volume of each of the second conductive posts.

19. The semiconductor package of claim 18, further comprising:
third conductive posts each extending through the first mold between the first and second RDLs and contacting the first and second redistribution wiring structures,
wherein the second conductive posts are arranged in a rectangular ring shape at a second distance from the first semiconductor chip in the horizontal direction, and the second distance being greater than the first distance and smaller than the second distance,
wherein a volume of each of the third conductive posts is greater than the volume of each of the first conductive posts and smaller than the volume of each of the second conductive posts.

20. The semiconductor package of claim 18, wherein an upper surface of each of the first conductive posts is coplanar with an upper surface of each of the second conductive posts, and
wherein a width in the horizontal direction of each of the first conductive posts is smaller than a width in the horizontal direction of each of the second conductive posts.
